(19) United States
(12) Patent Application Publication
(10) Pub. No.: US 2024/0281580 A1
(43) Pub. Date: Aug. 22, 2024

(54) LIBRARY CREATION DEVICE, LIBRARY CREATION METHOD, ANALYSIS DEVICE, AND ANALYSIS METHOD

(71) Applicant: Kioxia Corporation, Tokyo (JP)

(72) Inventor: Atsushi NAKAYAMA, Yokohama Kanagawa (JP)

(21) Appl. No.: 18/582,447

(22) Filed: Feb. 20, 2024

(30) Foreign Application Priority Data
Feb. 21, 2023 (JP) 2023-025067

(51) Int. Cl. G06F 30/3308; G06F 30/3323

(52) U.S. Cl. CPC G06F 30/3308; G06F 30/3315

(57) ABSTRACT

A library creation device for creating a library for circuit analysis of a semiconductor integrated circuit, includes a storage device, and a processor configured to: using a computer model corresponding to the integrated circuit, execute a simulation multiple times for calculating an expected value indicating an electrical characteristic of the integrated circuit and a variation of the expected value, for each of a plurality of sets of input parameters; and generate a library including the expected value and the variation for each of the sets of input parameters and statistical processing information indicating a condition of the executed simulation, and store the generated library in the storage device.

### CROSS-REFERENCE TO RELATED APPLICATION

This application is based upon and claims the benefit of priority from Japanese Patent Application No. 2023-025067, filed Feb. 21, 2023, the entire contents of which are incorporated herein by reference.

### FIELD

Embodiments described herein relate generally relates to a library creation device, a library creation method, an analysis device, and an analysis method.

### BACKGROUND

In a design of a semiconductor integrated circuit, static timing analysis (STA) using a timing library is executed. The timing library is data in which an expected value and the amount of variations of the electrical characteristics with respect to a parameter (hereinafter, simply referred to as a “parameter”) that affects the electrical characteristics of each of the logical elements provided in the semiconductor integrated circuit are stored. For example, in the STA of a semiconductor integrated circuit using a standard cell, a timing library in which the parameter dependency of the electrical characteristics for each standard cell is defined as a table, is used. There is a need for a high degree of accuracy of the electrical characteristics defined in the timing library in order to accurately calculate the electrical characteristics of the semiconductor integrated circuit by the STA.

### BRIEF DESCRIPTION OF THE DRAWINGS

FIG. 1 is a schematic diagram showing a configuration of a timing library according to an embodiment.

FIG. 2 is a graph showing an example of a relationship between a parameter and a signal propagation time.

FIG. 3 is a block diagram showing an example of a semiconductor integrated circuit.

FIG. 4 is a schematic diagram showing a transition prohibition period of a data signal in a D flip-flop.

FIG. 5 is a schematic diagram showing a timing library of a comparative example.

FIG. 6 is a graph showing an example of a relationship between a parameter reflecting a deviation and a signal propagation time.

FIG. 7 is a graph showing a comparative example of a relationship between a parameter and a signal propagation time.

FIG. 8 is a graph showing an example of a relationship between a parameter obtained using a timing library according to an embodiment and a signal propagation time.

FIG. 9 is a schematic diagram showing an example of a timing library in which an electrical characteristic is a signal propagation time.

FIG. 10 is a schematic diagram showing a configuration of a library creation device according to an embodiment.

FIG. 11 is a flowchart illustrating a creation method of a timing library according to an embodiment.

FIG. 12 is a schematic diagram showing a configuration of an analysis device according to an embodiment.

FIG. 13 is a flowchart illustrating an analysis method according to an embodiment.

FIG. 14 is a schematic diagram showing a configuration of a timing library according to another embodiment.

### DETAILED DESCRIPTION

Embodiments provide a library creation device and a library creation method that improve the accuracy of an amount of variations in electrical characteristics without increasing the creation time, and an analysis device and an analysis method for a semiconductor integrated circuit with higher accuracy using the timing library.

In general, according to one embodiment, a library creation device for creating a library for circuit analysis of a semiconductor integrated circuit, comprising: a storage device; and a processor configured to: using a computer model corresponding to the integrated circuit, execute a simulation multiple times for calculating an expected value indicating an electrical characteristic of the integrated circuit and a variation of the expected value, for each of a plurality of sets of input parameters; and generate a library including the expected value and the variation for each of the sets of input parameters and statistical processing information indicating a condition of the executed simulation, and store the generated library in the storage device.

Next, embodiments will be described with reference to the drawings. In the description of the drawings to be described below, the same or similar parts are denoted by the same or similar reference numerals. The drawings are schematic. In addition, the embodiments described below are examples of devices and methods for embodying the technical idea, and do not specify the material, shape, structure, disposition, and the like of the components. In the embodiment, various changes may be made.

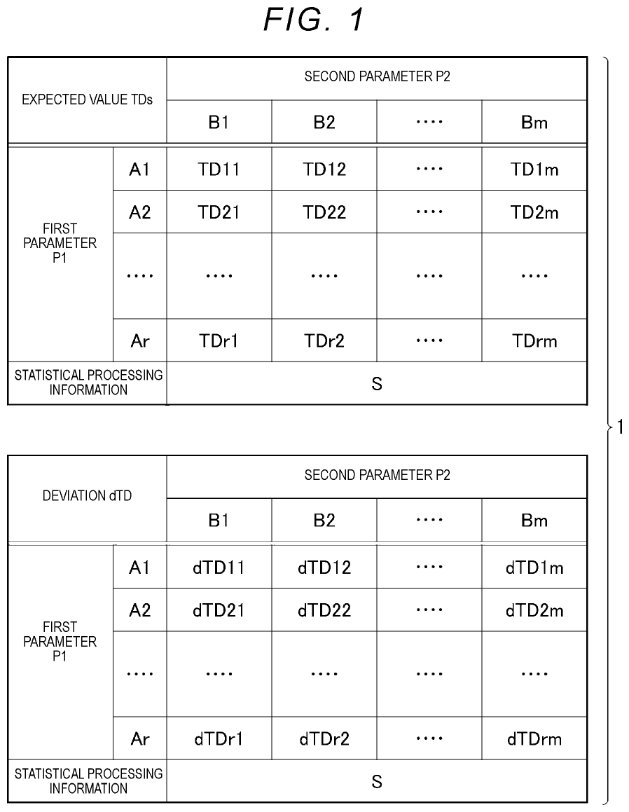

According to an embodiment of the present disclosure shown in FIG. 1, a timing library 1 is provided in which electrical characteristics of a unit circuit that constitutes a semiconductor integrated circuit is defined for circuit analysis thereof. For example, the timing library 1 is used for STA of the semiconductor integrated circuit. The unit circuit is a logical element that is included in a semiconductor integrated circuit, and is, for example, a standard cell. The timing library 1 is defined by an N-dimensional table for N parameters that affect the electrical characteristics of the unit circuit (N: an integer of 1 or more). Hereinafter, a table in which the timing library is defined is also referred to as a “library table”. The timing library 1 shown in FIG. 1 is defined by a two-dimensional library table corresponding to a first parameter P1 and a second parameter P2. The number N of parameters included in the timing library 1 may be 1 or 3 or more. Hereinafter, such parameters are denoted by “P”.

The timing library 1 shown in FIG. 1 includes a deviation dTD, as an index, representing the expected value TDs of the electrical characteristics of the unit circuit and an amount of variations of the expected value TDs. Furthermore, the timing library 1 includes statistical processing information S. The statistical processing information S is a value used to calculate the statistical confidence interval for the expected value TDs and the deviation dTD, and is, for example, the number of execution times of Monte Carlo simulation described later. The details of the statistical processing information S will be described later. A value other than the deviation may be used as an index representing the magnitude of the variations of the electrical characteristics.

In a library table, an electrical characteristic value measured at a plurality of measurement points represented by the parameter P is defined for each unit circuit. That is, in the library table defined as the timing library 1 of FIG. 1, for (r×m) measurement points defined by r measurement points of A1 to Ar of the first parameter P1 and m measurement points of B1 to Bm of the second parameter P2, the expected value TDs and the deviation dTD of the corresponding electrical characteristic value are described (r, m: natural numbers). Since the expected value or the deviation is discrete, in the circuit analysis in the STA, the values described in the library table are interpolated or extrapolated to complement between values described in the library table and use the values.

The electrical characteristics of the unit circuit is, for example, a signal propagation time, a temporal slope of an output signal output from the unit circuit, a power consumption, an input capacitance of an input terminal of the unit circuit, and a temporal development characteristic of a voltage or a current of the output signal. In addition, the parameters that affect the electrical characteristics such as the signal propagation time and the temporal slope of the output signal are, for example, the temporal slope of the input signal input to the unit circuit and the magnitude of an output load of the unit circuit. The “temporal slope of the input signal” represents a temporal change in a voltage level when a signal input to the input terminal of the unit circuit transitions. The “temporal slope of the output signal” represents a temporal change in the voltage level when a signal output from the output terminal of the unit circuit transitions. Hereinafter, the temporal slope is also referred to as a “slope”.

Hereinafter, a case where the unit circuit is a logical cell of the standard cell and the electrical characteristic is the signal propagation time in which the signal propagates through the unit circuit will be described. Hereinafter, the library table having the electrical characteristics as the signal propagation time is also referred to as a “propagation timetable”. In this case, the timing library 1 is defined by the propagation timetable including the expected value TDs and the deviation dTD of the signal propagation time, and the statistical processing information S, which are calculated in advance. In the analysis of the semiconductor integrated circuit, the propagation timetable in which the expected value and the deviation of the signal propagation time of the unit circuit constituting the semiconductor integrated circuit are defined is used for the calculation of the signal propagation time. The unit circuit is, for example, an inverter circuit cell, a NAND circuit cell, a flip-flop cell, or the like.

For example, in the timing library 1 shown in FIG. 1, the first parameter P1 may be “slope of the voltage of the input signal (V/s)”, and the second parameter P2 may be “magnitude of the output load (F)”. In this case, the measurement points of the parameter P when the electrical characteristic is the signal propagation time are defined by two parameters, that is, the slope (V/s) of the voltage of the input signal to the input terminal of the logical cell and the magnitude (F) of the output load connected to the output terminal.

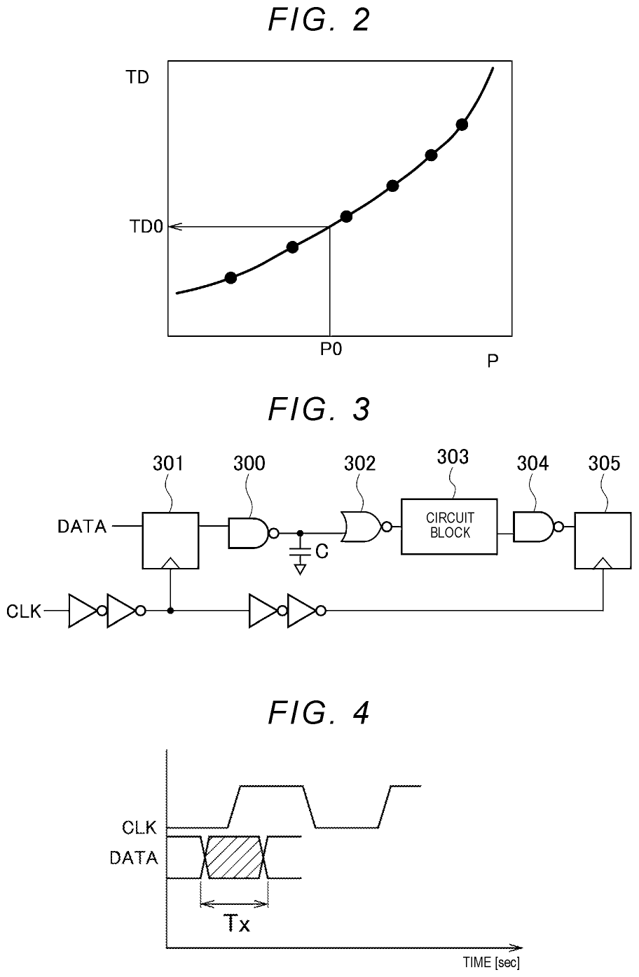

FIG. 2 shows an example of a relationship between the parameter P defined in the timing library 1 and the signal propagation time TD. Although the graph of FIG. 2 is two-dimensional for simplicity, it is actually “the number N of parameters+1” dimensional, and FIG. 2 can also be considered as a two-dimensional cross-sectional view thereof. In FIG. 2, the black circles are the expected values of the signal propagation time at the measurement points of the parameter P described in the propagation timetable. In the STA, a graph in which the time between the signal propagation times at the measurement points is complemented is used as shown in FIG. 2. For example, when the value of the parameter P in the logical cell corresponds to a measurement point P0, a propagation time TD0 is used as the expected value TDs of the signal propagation time of the logical cell.

FIG. 3 shows an example of a logical element provided in a semiconductor integrated circuit to be analyzed. In the circuit example shown in FIG. 3, a data signal DATA propagated through a first flip-flop 301 is input to an input terminal of a first NAND circuit 300. The data signal DATA output from an output terminal of the first NAND circuit 300 is input to a NOR circuit 302. An output load capacitance C of the output terminal of the first NAND circuit 300 is obtained by adding a wiring capacitance and an input terminal capacitance of the NOR circuit 302. An output of the NOR circuit 302 is input to a circuit block 303, and an output of the circuit block 303 is input to a second NAND circuit 304. An output of the second NAND circuit 304 is input to a second flip-flop 305. The first flip-flop 301 and the second flip-flop 305 are D flip-flops, and an operation thereof is controlled by a clock signal CLK.

As shown in FIG. 3, the signal propagation time from the time when the signal is input to the first NAND circuit 300 to the time when the signal is output is determined by a slope of the input signal input from the first flip-flop 301, the output load capacitance C, and the like. For example, in the timing library 1 of the first NAND circuit, the first parameter P1 may be used as a slope of the input signal input to the first NAND circuit 300. In addition, the second parameter P2 may be a magnitude of an output load capacitance C which is an output load of the first NAND circuit.

In the STA, for example, it is verified that a timing constraint of the D flip-flop is satisfied. As shown in FIG. 4, when a transition prohibition period Tx of the data signal DATA is present in the D flip-flop, in the STA, the signal propagation time of the data signal DATA and the clock signal CLK are calculated, and it is verified that the data signal DATA does not transition in the transition prohibition period Tx.

However, the signal propagation time of the semiconductor integrated circuit is affected by a shape of the element and the wiring that constitute the logical cell during the manufacturing process, and thus variations occur. For example, due to variations in the transition time of the transistor depending on variations in the gate length and the gate width, variations in the wiring resistance and the wiring capacitance depending on variations in the width of the wiring, and the like, variations in the signal propagation time occur.

In order to reflect the variations in the signal propagation time in the STA, a method is used in which a deviation in the signal propagation time due to the influence of the variations in the shape of the element or the wiring is calculated, and the deviation is used as a propagation timetable together with the expected value of the signal propagation time. The deviation of the expected value of the signal propagation time of the logical cell can be calculated by repeating a simulation many times at each measurement point (hereinafter, also referred to as “repeated simulation”). For example, the deviation of the signal propagation time of the logical cell is calculated by a repeated simulation using an electrical model of a circuit element (hereinafter, also referred to as an “element model”) including random variation components of an element and a wiring used for the logical cell. On the other hand, the expected value of the signal propagation time may be obtained by a simulation without variations, or may be obtained with a deviation by a repeated simulation. The expected value and the deviation obtained in this way are calculated at each measurement point, and then are created into a library. Then, the STA is executed using a propagation timetable including a deviation together with an expected value of a signal propagation time as a timing library. As the repeated simulation, for example, a Monte Carlo simulation or the like may be used.

Here, before describing the details of the timing library 1 according to an embodiment, an example of a timing library of a comparative example 1A (hereinafter, also referred to as a “comparative timing library”) will be described below.

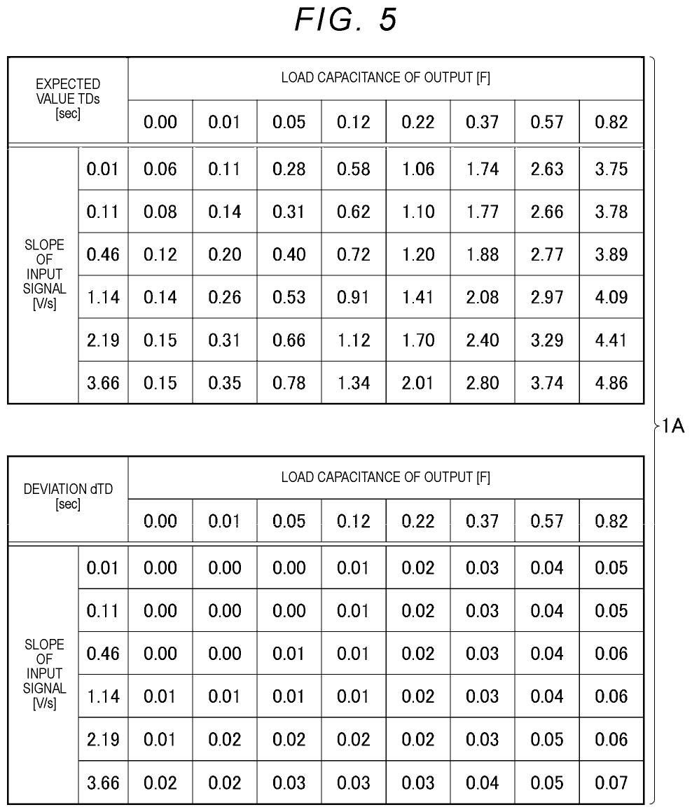

In the propagation timetable defining the comparative timing library 1A, the propagation time reflecting the expected value of the signal propagation time and the deviation of the signal propagation time are described. FIG. 5 shows an example of the comparative timing library 1A. In the comparative timing library 1A, the expected value TDs and the deviation dTD of the signal propagation time of the logical cell are defined in a two-dimensional propagation timetable by two parameters of the “slope of input signal” and the “load capacitance of output”.

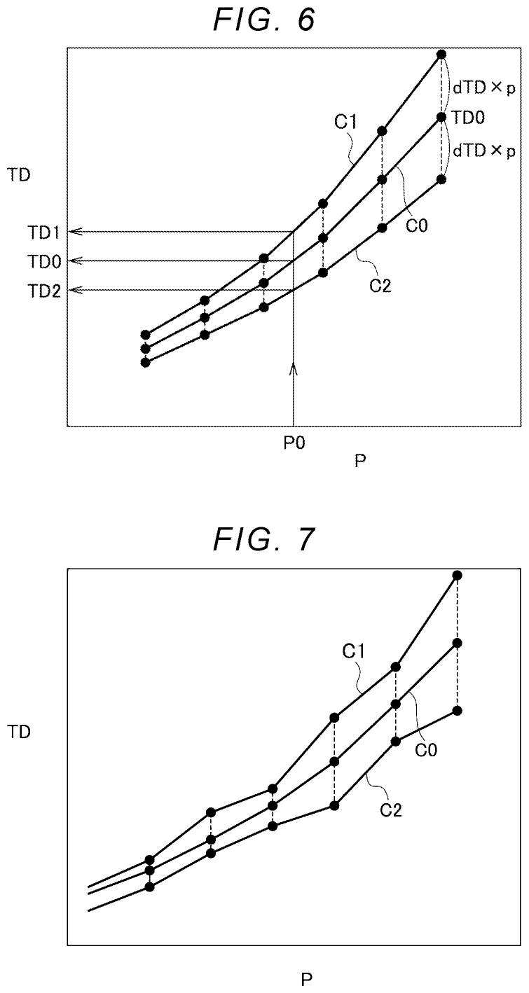

In STA, first, the upper and lower limits of the variations in the signal propagation time are calculated based on the expected value TDs and the deviation dTD of the signal propagation time described in the propagation timetable of the timing library, and the discrete expected value and the deviation are complemented. This aspect is shown in FIG. 6, but, as in FIG. 2, it is actually a graph of “the number N of parameters+1” dimensions, and FIG. 6 is a two-dimensional cross-sectional view thereof. The signal propagation time at the measurement point P0 of the parameter P has the upper and lower limits due to the influence of the shape of elements and wirings processed during manufacturing, and the values are TD1 and TD2 obtained by adding or subtracting the value obtained by multiplying the deviation dTD by the confidence coefficient p with respect to the expected value TDs. Next, since the expected value and the upper and lower limit values of the signal propagation time thus obtained are discrete values, the intervals therebetween are complemented, and the three N-dimensional curved surfaces of an expected value characteristic curved surface C0, a first deviation characteristic curved surface C1, and a second deviation characteristic curved surface C2 are calculated for the signal propagation time. The confidence coefficient p is set such that the probability that the semiconductor integrated circuit malfunctions due to the variations in signal propagation affected by the processing shape during manufacturing is sufficiently small. When the confidence coefficient p is set to be large, a robust circuit design can be performed against the variations in the processing shape during manufacturing, but the difference between the upper and lower limits of the signal propagation time, which guarantees the operation, becomes large. Therefore, in general, the performance of the semiconductor integrated circuit is limited, and the area of the circuit becomes large. Therefore, the confidence coefficient p is not necessarily a constant value even in a single semiconductor integrated circuit.

In the example shown in FIG. 6, when the value of the parameter P in the logical cell provided in the semiconductor integrated circuit to be analyzed corresponds to the measurement point P0, the propagation time TD0 is used as the expected value TDs of the signal propagation time TD of the logical cell. In addition, the first propagation time TD1 at the measurement point P0 obtained from the first deviation characteristic curved surface C1 and the second propagation time TD2 at the measurement point P0 obtained from the second deviation characteristic curved surface C2 indicate the upper and lower limits of the variations in the signal propagation time at the measurement point P0. In FIG. 6, for simplicity, the confidence coefficient p is 1. By using the first propagation time TD1 and the second propagation time TD2 for the analysis of the propagation signals of the data signal and the clock signal, more accurate STA can be executed. For example, when a propagation speed of the data signal is slow and a propagation speed of the clock signal is fast, a setup failure occurs due to the transition prohibition period Tx of the D flip-flop occurs. Therefore, in a setup analysis, the first propagation time TD1 is used as the propagation time of the data signal, and the second propagation time TD2 is used as the propagation time of the clock signal, so that more accurate STA is realized by taking into account the influence of the processing shape during manufacturing.

The deviation used as an index of the variations in the signal propagation time is a value estimated by repeated simulations such as Monte Carlo simulations, is not deterministic, and has a confidence interval having a statistical width. In order to accurately execute STA, it is necessary that the deviation is close to the true value, that is, the confidence interval of the deviation is sufficiently small. In order to make the confidence interval sufficiently small, it is necessary to increase the number of repetitions of the simulation. However, in general, even if the convergence of the deviation with respect to the number of repetitions is very slow, and the number of repetitions of the simulation is increased by 10 times, the width of the statistical confidence interval is improved only to the order of a fraction. Therefore, a development period of the timing library is increased several times even if the statistical confidence interval is reduced by one digit. The expected value of the signal propagation time can be determined by simulation using an element model that does not include the variation component, but when the expected value is calculated together with the variations by repeated simulation, the expected value has a confidence interval. In this case, it is required that the confidence interval is sufficiently small, as in the case of the deviation.

As described above, it takes a very long time to measure the deviation with sufficient accuracy, and the time for creating the timing library increases. On the other hand, the development period of the timing library can be shortened by reducing the number of repetitions of the simulation. However, when the number of repetitions of the simulation is reduced, the accuracy of the deviation is reduced. When the accuracy of the deviation is insufficient, as in the comparative example shown in FIG. 7, the first deviation characteristic curved surface C1 and the second deviation characteristic curved surface C2 is curved surfaces with uneven portion, and the accuracy of the STA decreases.

Meanwhile, the timing library 1 according to an embodiment includes the statistical processing information S required to calculate the statistical confidence interval for the expected value TDs and the deviation dTD of the signal propagation time, and indicates that the expected value and the deviation are estimated values obtained by the repeated simulation. In the present embodiment, by including the statistical processing information S in the timing library 1, it is possible to narrow the interval between the first deviation characteristic curved surface C1 and the second deviation characteristic curved surface C2 of the signal propagation time TD calculated during STA is executed, while minimizing the number of repetitions of the simulation. As a result, the accuracy of the signal propagation time can be improved. That is, in the STA, first, for each individual measurement point described in the timing library 1, the statistical processing information S is used to calculate the statistical confidence interval from the expected value, the deviation, and the confidence coefficient p. Next, a certain N-dimensional characteristic curved surface is regressed and estimated from a plurality of measurement points and confidence intervals thereof by a statistical analysis method. In this manner, even if the accuracy of the expected value or the deviation at each measurement point is low due to the small number of repetitions of simulation, the confidence interval can be calculated from the statistical processing information S included in the timing library in the STA. Furthermore, in the STA, it is possible to reliably regress statistical estimation from the discrete expected value and the deviation. That is, even if the calculated value of each measurement point includes an error, the plurality of measurement points and the confidence interval are corrected and complemented, so that the influence of the error can be reduced. In the present embodiment, when the expected value TDs is determined, the statistical processing information S is not included in the TDs. In addition, for the regression estimation, either a parametric method or a non-parametric method may be used.

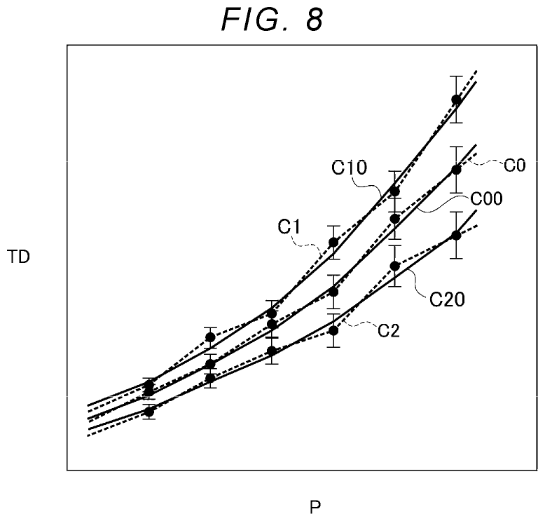

FIG. 8 shows an example of a relationship between the parameter P defined in the timing library 1 and the signal propagation time TD. As in FIG. 2, the graph is actually a graph of a “the number N of parameters+1” dimensions, and FIG. 8 is a two-dimensional cross-sectional view thereof. The black circles indicate the expected values and the deviations of the signal propagation time at the measurement points of the parameter P described in the propagation timetable. The uneven portion of the expected value characteristic curved surface C0, the first deviation characteristic curved surface C1, and the second deviation characteristic curved surface C2, which are the dashed lines connecting the expected values and the deviations, indicate that the error between the expected value and the deviation is large due to the small number of simulations. In addition, in FIG. 8, the statistical confidence intervals of the expected value and deviation of the signal propagation time TD calculated using the statistical processing information S defined in the timing library 1 are indicated by the error bars. Further, a correction expected value characteristic curved surface C00, a first correction deviation characteristic curved surface C10, and a second correction deviation characteristic curved surface C20, which are three N-dimensional characteristic curved surfaces regressed and estimated by the statistical analysis method from the statistical confidence intervals, are indicated by solid lines. In FIG. 8, for simplicity, the confidence coefficient p is 1.

As described above, by using the timing library 1, the confidence interval of each measurement point of the N-dimensional library table can be calculated using the statistical processing information S in the STA, and the regression curved surface in which the measurement point is reliably corrected and complemented can be estimated. For example, in the STA using the timing library 1, where the electrical characteristics of the logical cell represent the signal propagation time, it is possible to obtain smoother and more reliable correction expected value characteristic curved surface C00, first correction deviation characteristic curved surface C10, and second correction deviation characteristic curved surface C20 compared to the expected value characteristic curved surface C0, first deviation characteristic curved surface C1, and second deviation characteristic curved surface C2 in the related art. As a result, even when a library having excellent productivity, but poor accuracy is used, the STA having high accuracy can be executed.

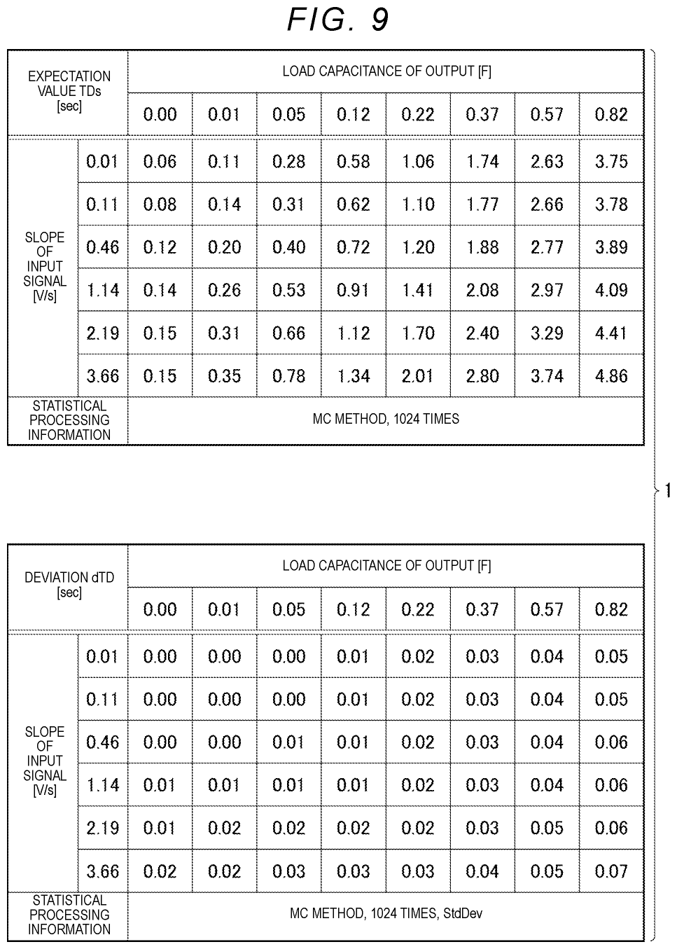

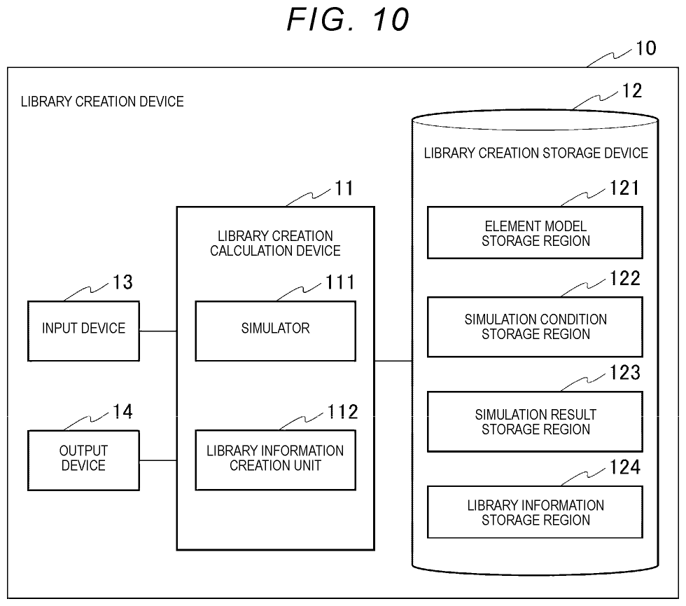

For example, a method of repeated simulation or the number of its repetitions may be used as the statistical processing information representing the statistical confidence interval. FIG. 9 shows an example in which it is defined that a Monte Carlo method (denoted by “MC method”) is used as the repeated simulation, the number of repetitions of the simulation is 1024, and the standard deviation (denoted by “StdDeV”) of dTD is adopted as statistical processing information. In this way, by indicating the type and the number of repetitions of the simulations, the confidence interval can be calculated in the STA.

The timing library 1 is created and generated using, for example, a library creation device 10 shown in FIG. 10. The library creation device 10 includes a library creation calculation device 11 and a library creation storage device 12. For example, the unit circuit is a logical cell, and the electrical characteristic is a signal propagation time.

The library creation calculation device 11 includes a processor such as a central processing unit (CPU) to perform the function of a simulator 111 and a library information creation unit 112.

The simulator 111 executes a repeated simulation using an element model including a variation component of a logical cell (hereinafter, also referred to as a “target logical cell”) for which a timing library is to be created. The repeated simulation may be, for example, a Monte Carlo simulation. The simulator 111 repeatedly executes the simulation in accordance with the statistical processing information to calculate the expected value and the deviation of the electrical characteristics of the target logical cell.

The library information creation unit 112 creates the timing library information to be stored in the timing library 1 from the simulation result calculated by the repeated simulation. For example, the library information creation unit 112 generates a data library of the expected value and the deviation of the signal propagation time of the target logical cell, which are calculated by the repeated simulation using the element model, together with the statistical processing information.

The library creation storage device 12 includes an element model storage region 121, a simulation condition storage region 122, a simulation result storage region 123, and a library information storage region 124.

An element model including a variation component of the target logical cell is stored in the element model storage region 121. The simulation condition used in the repeated simulation using the element model is stored in the simulation condition storage region 122. The simulation condition includes information on the measurement points of the parameter P and statistical processing information representing a statistical confidence interval of the deviation of the electrical characteristics. The statistical processing information is, for example, the type of the repeated simulation and the number of repetitions of the simulation. The simulation result calculated by the simulator 111 is stored in the simulation result storage region 123. The simulation result includes an expected value and a deviation of the electrical characteristics of the target logical cell at each of the plurality of measurement points of the parameter P. The timing library information created by the library information creation unit 112 is stored in the library information storage region 124.

The timing library creator can specify input and output data from an input device 13 of the library creation device 10. For example, the timing library creator can specify the target logical cell, the measurement point of the parameter P, the simulation condition, and the like. Further, it is also possible to set a form of the output data and the like from the input device 13, and it is also possible to input an instruction to execute or stop the timing library creation. The input device 13 is a keyboard, a mouse, a light pen, a flexible disk device, or the like.

The created timing library information can be output from an output device 14 of the library creation device 10. As the output device 14, an interface circuit capable of transferring data between storage devices storing the timing library 1, a storage device storing timing library information in a non-transitory computer-readable storage medium, or the like may be used. Here, the “non-transitory computer-readable storage medium” means, for example, a medium that can store electronic data such as an external storage device of a computer and a semiconductor memory.

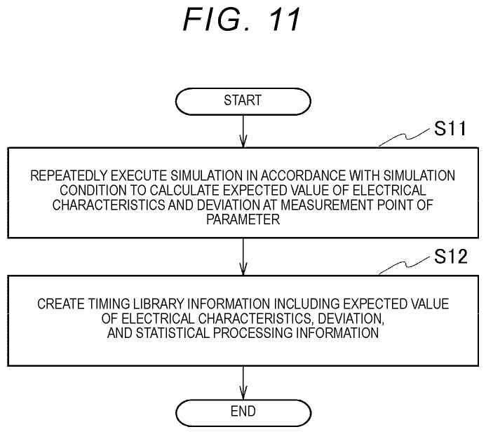

An example of a creation method of the timing library 1 using the library creation device 10 will be described with reference to FIG. 11.

First, in step S11, the simulator 111 reads an element model including a variation component of the target logical cell from the element model storage region 121. Further, the simulator 111 reads the simulation conditions used in the repeated simulation from the simulation condition storage region 122. Then, the simulator 111 repeatedly executes the simulation using the read element model in accordance with the simulation condition to calculates the expected value TDs of the electrical characteristics and the deviation dTD of the expected value TDs at the measurement point of the parameter P of the target logical cell. For example, the simulator 111 calculates the expected value TDs and the deviation dTD of the signal propagation time at the plurality of measurement points of the parameter P. The expected value TDs and the deviation dTD of the electrical characteristics of the target logical cell calculated for each parameter P are stored in the simulation result storage region 123. Further, the simulator 111 stores statistical processing information regarding the simulation conditions applied to the repeated simulation in the simulation result storage region 123.

Next, in step S12, the library information creation unit 112 reads the expected value TDs and the deviation dTD of the electrical characteristics calculated for the target logical cell from the simulation result storage region 123. Further, the library information creation unit 112 reads the statistical processing information from the simulation result storage region 123. The library information creation unit 112 creates timing library information including the expected value TDs and the deviation dTD of the electrical characteristics with respect to the parameter P of the target logical cell and the statistical processing information. For example, the library information creation unit 112 creates a library table that defines the timing library 1 shown in FIG. 1. When the number of parameters P that affect the target logical cell is N, for example, an N-dimensional library table having N parameters P as items is created. The created timing library information is stored in the library information storage region 124.

The creation method of the timing library 1 shown in FIG. 11 can be executed by the library creation device 10 shown in FIG. 10 according to a control program of an algorithm equivalent to FIG. 11. The control program that executes an instruction for controlling the library creation device 10 may be stored in the library creation storage device 12 that is included in the library creation device 10. The library creation storage device 12 can be used as a non-transitory computer-readable storage medium.

In the above description, the case where the expected value and the deviation of the electrical characteristics are calculated by the element model including the variation component has been described, but the expected value of the electrical characteristics may be determinedly calculated by the element model not including the variation component.

In a case of a logical cell having an inflection point in electrical characteristics such as a signal propagation time, it is preferable to increase the number of measurement points in the around the periphery of the inflection point in order to complement or estimate between the measurement points by STA. Therefore, when the simulator 111 detects that the inflection point is present in the electrical characteristics of the logical cell defined in the timing library 1, the number of measurement points in the around the periphery of the inflection point may be increased. In addition, the number of measurement points is increased, and the number of repetitions of the repeated simulation may be reduced. As a result, it is possible to prevent an increase in the creation time of the timing library 1 when the electrical characteristics of the logical cell have an inflection point.

Monte Carlo simulation is performed at each measurement point represented by the two-dimensional table in FIG. 1. An inflection point is found in the characteristic curve complemented by expected values of the signal propagation time. In order for the complemented curve to be more accurately near the inflection point, it is necessary to add some measurement points near the inflection point (see FIG. 2). In other words, the intervals between the vertical or horizontal axes of the table shown in FIG. 1 should be made finer around the inflection point. As mentioned above, as the number of measurement points increases, the statistical confidence interval narrows. Conversely, the number of repeated simulations to obtain the same level of statistical confidence interval can be reduced.

According to the creation method of the timing library 1 described above, the timing library 1 including the statistical processing information representing the statistical confidence interval such as the number of repetitions of the repeated simulation is created. A feature of the timing library 1 is to provide a statistical confidence interval calculation unit for the electrical characteristics appropriately applied to the library to an analysis device or an analysis method such as STA.

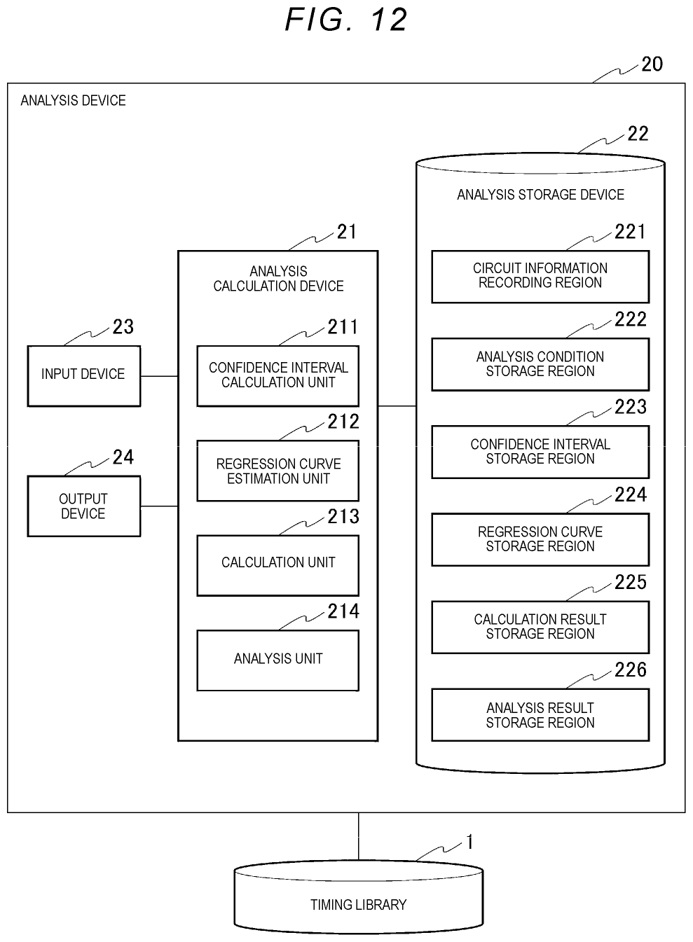

Hereinafter, STA using the timing library 1 will be described. For example, the unit circuit is a logical cell, and the electrical characteristic is a signal propagation time. The STA is executed by, for example, the analysis device 20 shown in FIG. 12. The analysis device 20 includes an analysis calculation device 21 and an analysis storage device 22. The timing library 1 includes timing library information including the expected value TDs and the deviation dTD of the electrical characteristics of the logical cell provided in the semiconductor integrated circuit to be analyzed (hereinafter, also referred to as an “analysis target circuit”) and statistical processing information.

The analysis calculation device 21 includes a processor such as a CPU to perform the function of a confidence interval calculation unit 211, a regression curve estimation unit 212, a calculation unit 213, and an analysis unit 214.

The confidence interval calculation unit 211 calculates a statistical confidence interval for each of the plurality of measurement points of the parameter P using the statistical processing information defined in the timing library 1 and the accuracy required in the STA (hereinafter, also referred to as “required accuracy”). For example, the statistical processing information is the type and the number of repetitions the repeated simulation executed for the creation of the timing library 1. The required accuracy is, for example, 3σ.

A regression curve estimation unit 212 estimates a regression curve that regresses statistical confidence intervals of a plurality of measurement points using a statistical method to satisfy the required accuracy. For simplicity, it is referred to as a regression curve, but actually, it is an N-dimensional curved surface when the number of parameters P is N. For example, the regression curve estimation unit 212 performs regression estimation on the regression curve of the deviation having the propagation time longer than the expected value TDs and the regression curve of the deviation having the propagation time shorter than the expected value TDs, respectively, from the expected value TDs and the deviation dTD of the signal propagation time and the statistical confidence interval. That is, as illustrated in FIG. 8, for example, the regression curve estimation unit 212 reliably corrects the first deviation characteristic curved surface C1 and the second deviation characteristic curved surface C2, which have a zigzag curve, to the first correction deviation characteristic curved surface C10 and the second correction deviation characteristic curved surface C20, which have a smooth curve, using a statistical analysis method.

The calculation unit 213 sets a value of the parameter P of the logical cell using a circuit information of the analysis target circuit. The calculation unit 213 calculates the electrical characteristics of each of the logical cells using the regression curve estimated by the regression curve estimation unit 212. For example, the calculation unit 213 calculates the signal propagation time of the analysis target circuit using the regression curve.

The analysis unit 214 analyzes an operation of the analysis target circuit using the electrical characteristics calculated by the calculation unit 213. The analysis unit 214 verifies whether the analysis target circuit operates normally. For example, the analysis unit 214 verifies whether the operation of the flip-flop of the analysis target circuit violates the timing constraint, by using the signal propagation time calculated by the calculation unit 213.

The analysis storage device 22 includes a circuit information recording region 221, an analysis condition storage region 222, a confidence interval storage region 223, a regression curve storage region 224, a calculation result storage region 225, and an analysis result storage region 226.

The circuit information of the analysis target circuit is stored in the circuit information recording region 221. The circuit information includes information used in the STA, such as the type and layout information of the logical cell provided in the semiconductor integrated circuit, the electrical connection information between the logical cells, and the electrical connection information between the logical cell and an external terminal.

An analysis condition for executing the STA is stored in the analysis condition storage region 222. The analysis conditions include setting of a clock signal when the analysis target circuit is operated, a voltage level or a power supply voltage of a signal, an ambient temperature, a timing constraint for the analysis target circuit to operate normally, and the like. In addition, the analysis condition includes the required accuracy required in the STA.

The statistical confidence interval calculated by the confidence interval calculation unit 211 is stored in the confidence interval storage region 223. The regression curve estimated by the regression curve estimation unit 212 is stored in the regression curve storage region 224. The calculation result by the calculation unit 213 is stored in the calculation result storage region 225. The analysis result by the analysis unit 214 is stored in the analysis result storage region 226.

The data used in the analysis device 20 is input from an input device 23 of the analysis device 20. An analyst who executes the STA can specify the input and output data from the input device 23. For example, the analyst can specify circuit information of the analysis target circuit. Further, it is also possible to set a form of the output data and the like from the input device 23, and it is also possible to input an instruction to execute or stop the analysis. The input device 23 is a keyboard, a mouse, a light pen, a flexible disk device, or the like.

An output device 24 outputs the result of the STA. As the output device 24, a display, a printer, a storage device that stores the result of the analysis in a computer-readable storage medium, or the like may be used.

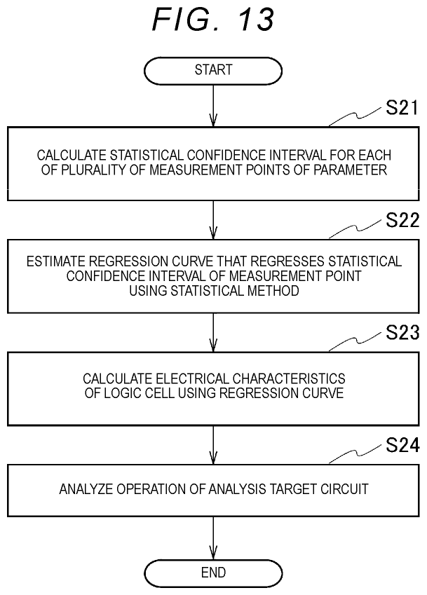

An example of the STA using the analysis device 20 will be described below with reference to FIG. 13.

First, in Step S21, the confidence interval calculation unit 211 reads the circuit information of the analysis target circuit from the circuit information recording region 221. Further, the confidence interval calculation unit 211 reads the required accuracy from an analysis condition storage region 222. The confidence interval calculation unit 211 calculates the statistical confidence interval for each of the plurality of measurement points of the parameter P from the statistical processing information obtained by referring to the timing library 1 and the required accuracy of the STA for each of the logical cells provided in the analysis target circuit. The calculated statistical confidence interval is stored in the confidence interval storage region 223.

In Step S22, the regression curve estimation unit 212 reads a statistical confidence interval from a confidence interval storage region 223 and reads the required accuracy from the analysis condition storage region 222. The regression curve estimation unit 212 estimates a regression curve that regresses the statistical confidence intervals of the plurality of measurement points using a statistical method for each parameter P of the logical cell to satisfy the required accuracy. The estimated regression curve is stored in the regression curve storage region 224. As a statistical analysis method in the STA, for example, a nonparametric estimation method, a parametric estimation, or the like may be used.

In Step S23, the calculation unit 213 reads the circuit information of the analysis target circuit from the circuit information recording region 221 and reads the regression curve of the logical cell from the regression curve storage region 224. The calculation unit 213 sets the value of the parameter P of the logical cell using the circuit information of the analysis target circuit, and calculates the electrical characteristics of the logical cell for each of the logical cells constituting the analysis target circuit using the expected value and the regression curve. The calculated electrical characteristics are stored in the calculation result storage region 225. For example, the signal propagation time calculated by the calculation unit 213 is stored in the calculation result storage region 225.

In Step S24, the analysis unit 214 reads the electrical characteristics from the calculation result storage region 225 and reads the analysis condition from the analysis condition storage region 222. The analysis unit 214 analyzes the operation of the analysis target circuit with reference to the analysis condition. The analysis result is stored in the analysis result storage region 226. The analyst can confirm the analysis result through the output device 24.

The analysis method of semiconductor integrated circuits shown in FIG. 13 can be executed by the analysis device 20 shown in FIG. 12 according to a control program of an algorithm equivalent to FIG. 13. The control program that executes the instruction for controlling the analysis device 20 may be stored in the analysis storage device 22 that is included the analysis device 20. The analysis storage device 22 can be used as a non-transitory computer-readable storage medium.

In the analysis method according to the embodiment described above, the regression curve estimated using the expected value and the deviation defined in the timing library 1 are used to calculate the electrical characteristics of each unit circuit constituting the semiconductor integrated circuit. Therefore, the accuracy of the STA can be improved without increasing the development period of the timing library by increasing the number of repetitions of the simulation. That is, the number of repetitions can be reduced to shorten the development period of the timing library without degrading the accuracy of the STA.

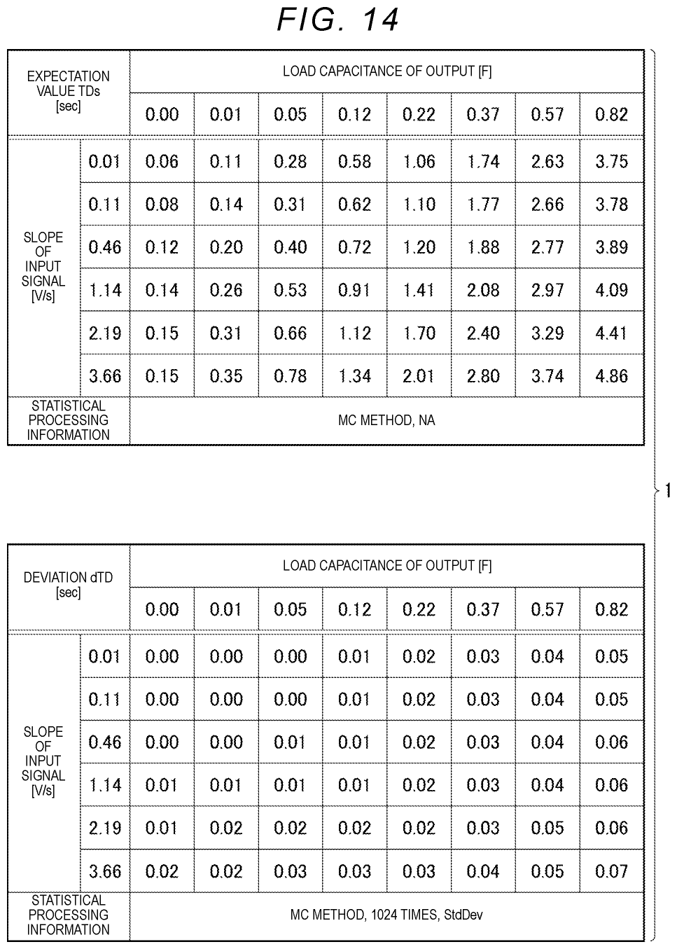

The expected value TDs of the electrical characteristics may be determinedly calculated by an element model that does not include the variation component. For example, as illustrated in FIG. 14, it is represented that the expected value is determined regardless of the repeated simulation, since “NA” meaning that there is no repetition of simulation is defined in the statistical processing information.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A library creation device for creating a library for circuit analysis of a semiconductor integrated circuit, the library creation device comprising:
a storage device; and
a processor configured to:
using a computer model corresponding to the integrated circuit, execute a simulation multiple times for calculating an expected value indicating an electrical characteristic of the integrated circuit and a variation of the expected value, for each of a plurality of sets of input parameters; and
generate a library including the expected value and the variation for each of the sets of input parameters and statistical processing information indicating a condition of the executed simulation, and store the generated library in the storage device.

2. The library creation device according to claim 1, wherein the library includes an N-dimensional table where N is a total number of the input parameters.

3. The library creation device according to claim 1, wherein the electrical characteristic is one of: a signal propagation time, a temporal slope of an output signal, a power consumption, a capacitance of an input terminal, and a temporal characteristic of a voltage or a current of the output signal.

4. The library creation device according to claim 1, wherein the statistical processing information indicates a type of the simulation and a total number of executions of the simulation for each of the sets of input parameters.

5. The library creation device according to claim 1, wherein the processor is configured to:
determine whether there is an inflection point in the expected values, and
upon determining that there is an inflection point in the expected values, execute a further simulation multiple times for each of additional sets of input parameters selected based on the inflection point.

6. The library creation device according to claim 5, wherein the processor is configured to reduce a total number of executions of the further simulation for each of the sets of input parameters when there is an inflection point in the expected values.

7. The library creation device according to claim 1, wherein the statistical processing information indicates a statistical confidence interval of the expected value and the variation.

8. A library creation method for creating a library for circuit analysis of a semiconductor integrated circuit, the method comprising:
using a computer model corresponding to the integrated circuit, executing a simulation multiple times for calculating an expected value indicating an electrical characteristic of the integrated circuit and a variation of the expected value, for each of a plurality of sets of input parameters; and
generating a library including the expected value and the variation for each of the sets of input parameters and statistical processing information indicating a condition of the executed simulation, and storing the library in a storage device.

9. The library creation method according to claim 8, wherein the library includes an N-dimensional table where N is a total number of the input parameters.

10. The library creation method according to claim 8, wherein the electrical characteristic is one of: a signal propagation time, a temporal slope of an output signal, a power consumption, a capacitance of an input terminal, and a temporal characteristic of a voltage or a current of the output signal.

11. The library creation method according to claim 8, wherein the statistical processing information indicates a type of the simulation and a total number of executions of the simulation for each of the sets of input parameters.

12. The library creation method according to claim 8, further comprising:
determining whether there is an inflection point in the expected values; and
upon determining that there is an inflection point in the expected values, executing a further simulation multiple times for each of additional sets of input parameters selected based on the inflection point.

13. The library creation method according to claim 12, further comprising:
reducing a total number of executions of the simulation for each of the sets of input parameters when there is an inflection point in the expected values.

14. The library creation method according to claim 8, wherein the statistical processing information indicates a statistical confidence interval of the expected value and the variation.

15. A non-transitory computer-readable medium storing the library created by the library creation method according to claim 8.

16. An analysis device for analyzing an electrical characteristic of a semiconductor integrated circuit, the analysis device comprising:
a storage device that stores a library created by a simulation using a computer model of the integrated circuit and in which a first value indicating the electrical characteristic of the integrated circuit is associated with a variation of the value for each of a plurality of sets of input parameters, the library including statistical processing information indicating a condition of the simulation; and
a processor configured to:
calculate a statistical confidence interval of the first value and the variation using the statistical processing information,
determine a regression curve that regresses the statistical confidence interval using a statistical analysis method,
calculate a second value indicating the electrical characteristic of the integrated circuit using the regression curve, and
storing the second value in the storage device.

17. The analysis device according to claim 16, wherein the library includes an N-dimensional table where N is a total number of the input parameters.

18. The analysis device according to claim 16, wherein the electrical characteristic is one of: a signal propagation time, a temporal slope of an output signal, a power consumption, a capacitance of an input terminal, and a temporal characteristic of a voltage or a current of the output signal.

19. The analysis device according to claim 16, wherein the statistical processing information indicates a type of the simulation and a total number of executions of the simulation for each of the sets of parameters.
